(19) United States
(12) Patent Application Publication
(10) Pub. No.: US 2008/0089126 A1
(43) Pub. Date: Apr. 17, 2008

(54) CIRCUITRY FOR RELIABILITY TESTING AS A FUNCTION OF SLEW

(75) Inventors: Andrew Marshall, Dallas, TX (US); Robert L. Pitts, Dallas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/536,884

(22) Filed: Sep. 29, 2006

(51) Int. Cl. G11C 16/04

(52) U.S. Cl. 365/185.17

(57) ABSTRACT

A reliability test chain includes: a stress chain; and transition time control circuits coupled to tap points along the stress chain such that transition times of a signal on the stress chain are controlled.

### FIELD OF THE INVENTION

The present invention relates to electronic circuitry and, in particular, to circuitry for reliability testing as a function of slew.

### BACKGROUND OF THE INVENTION

Various stress modes (such as channel hat carrier (CHC) and negative bias temperature instability (NBTI) effects) can degrade transistors. It is currently not well understood whether degradation is affected by different turn-on/turn-off rates.

Previous designs to analyze the reliability effects of switching effects have used oscillators to define the switching period. One method uses a ring oscillator internal to the chip that is provided with current control. This current control can be supplied from a source external to the chip. As current is increased from zero, the frequency of the oscillator increases, until it approaches that of the circuitry under stress. To improve linearity at lowest frequencies, a switchable divider is employed. Before and after stress, the circuitry under test is configured as a free running ring oscillator to measure before and after transistor degradation, as shown in FIG. 1. In addition, a divider included as part of the ring oscillator output may be used to monitor the frequency of the current controlled ring oscillator.

The prior art device of FIG. 1 includes current controlled oscillator 20; multiplexer (mux) 22; test inverters 24; and divider 26. The current controlled oscillator 20 is adjusted to give the desired frequency through the test inverters 22 (or other gates), by selecting the mux state to receive the current controlled oscillator signal. The devices under test usually also are stressed at a higher voltage. The stress frequency and current controlled oscillator frequency are determined from the output frequency, which is a divided percentage of the stress frequency. Once stressing is complete the mux 22 is set to convert the stressed devices into a free-running ring oscillator to measure the post stress frequency.

### SUMMARY OF THE INVENTION

A reliability test chain includes: a stress chain; and transition time control circuits coupled to tap points along the stress chain such that transition times of a signal on the stress chain are controlled.

### BRIEF DESCRIPTION OF THE DRAWINGS

In the drawings:

FIG. 1 is a circuit diagram of a basic prior art test structure with oscillator and stress chain;

FIG. 2 is a circuit diagram of a preferred embodiment stress chain with slew rate control.

### DETAILED DESCRIPTION OF PREFERRED EMBODIMENTS

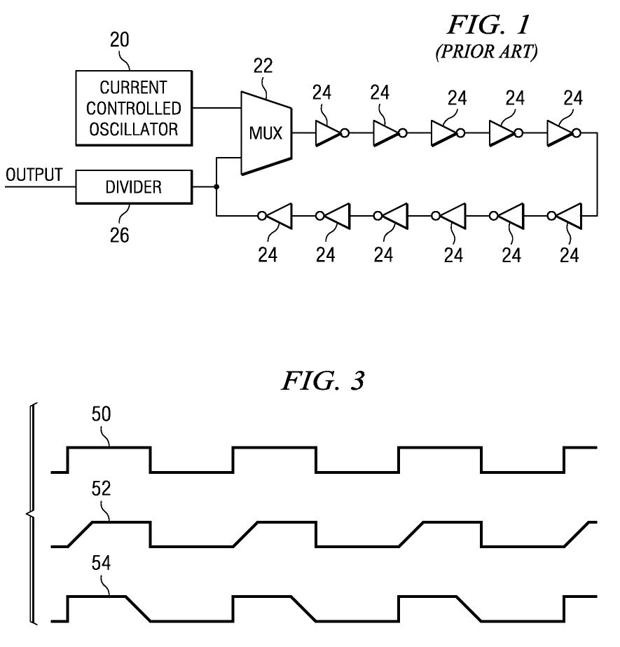

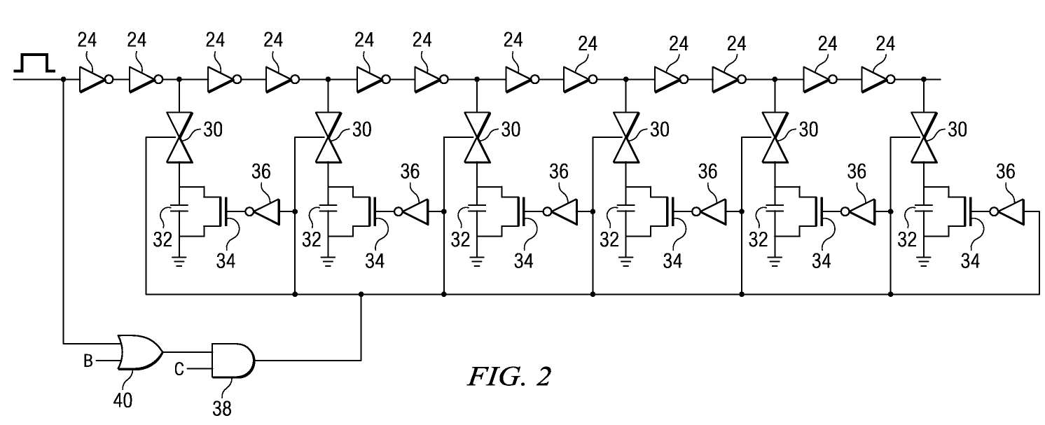

The preferred embodiment circuit, shown in FIG. 2, is a stress-chain that permits independent rise and fall times along a reliability chain. The circuit of FIG. 2 is a replacement for the stress-chain of FIG. 1. The preferred embodiment circuit permits the rising and falling edges of the chain under test to be selectively switched. The circuit of FIG. 2 includes test inverters 24; transition time control circuits which include: pass gates 30, capacitors 32, discharging transistors 34, and inverters 36; AND gate 38; and OR gate 40. With the OR gate 40 input B low and the AND gate 38 input C high, the switching signal propagates through the control gates 38 and 40. As the switching signal rises, the pass gates 30 to the capacitors 32 turn-on, and the rise time of the output or input being stressed is slow. As the switching input signal switches low, the pass gates 30 are turned off (high impedance), the capacitors 32 are discharged, and the switching time of the output or input is fast. To control the signal manually the inputs B and C to gates 38 and 40 can be switched (C is low for always off, B and C are high for always on). An independent signal can be generated rather than relying on the switching of the chain input.

FIG. 3 is a plot showing unskewed I/O waveform 50, rise skew 52, and fall skew 54. The plot of FIG. 3 shows waveform skew resulting from the selectable capacitances. The waveform for increasing falling edge time of decay requires clamp transistors to be tied to Vdd, not ground.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A reliability test chain comprising:
a stress chain; and
transition time control circuits coupled to tap points along the stress chain such that transition times of a signal on the stress chain are controlled.

2. The device of claim 1 wherein the transition time control circuits comprise:
a transmission gate coupled to the stress chain;
a capacitor coupled to the transmission gate; and,
a discharging transistor coupled to the capacitor.

3. The device of claim 1 wherein the stress chain comprises an inverter chain.

4. The device of claim 1 further comprising a logic device coupled between an input of the stress chain and control nodes of the transition time control circuits.

5. The device of claim 2 further comprising a logic device coupled between an input of the stress chain and a control node of the transmission gate.

6. The device of claim 5 wherein a control node of the discharging transistor is coupled to the logic device.

7. The device of claim 5 wherein the logic device comprises an OR gate coupled to the input of the stress chain and an AND gate coupled to the OR gate.

8. A reliability test chain comprising:
a stress chain;
a transmission gate coupled to the stress chain;
a capacitor coupled to the transmission gate;
a discharging transistor coupled to the capacitor, wherein the transmission gate and the discharging transistor are controlled such that a transition time of a signal on the stress chain is reduced.

9. The device of claim 8 wherein the stress chain comprises an inverter chain.

10. The device of claim 8 further comprising a logic device coupled between an input of the stress chain and a control node of the transmission gate.

11. The device of claim 10 wherein a control node of the discharging transistor is coupled to the logic device.

12. The device of claim 10 wherein the logic device comprises an OR gate coupled to the input of the stress chain and an AND gate coupled to the OR gate.
